(19) United States
(12) Patent Application Publication
(10) Pub. No.: US 2026/0150225 A1
(43) Pub. Date: May 28, 2026

(54) ELECTRONIC DEVICE

(71) Applicant: COOLER MASTER TECHNOLOGY INC., Taipei City (TW)

(72) Inventor: Yun-Han SHIH, Taipei City (TW)

(73) Assignee: COOLER MASTER TECHNOLOGY INC., Taipei City (TW)

(21) Appl. No.: 19/395,388

(22) Filed: Nov. 20, 2025

(30) Foreign Application Priority Data
Nov. 22, 2024 (TW) 113212795

(51) Int. Cl. H05K 7/20

(52) U.S. Cl. CPC H05K 7/20145

(57) ABSTRACT

An electronic device includes a housing having a housing body, a cover containing a first side panel and a second side panel, the housing having an accommodation space, the first and second side panels covering adjacent sides of the accommodation space, the first side panel having an air inlet, the second side panel having an air outlet, the air inlet and air outlet are configured to communicate with the accommodation space, an intake fan disposed in the accommodation space, the intake fan being adjacent to the first side panel, and a wind deflector disposed on the first side panel, the wind deflector having at least one ventilation opening corresponding to the intake fan, and the air inlet is configured to communicate with the accommodation space through the at least one ventilation opening.

### RELATED APPLICATIONS

This US application claims priority to Taiwan Application No. 113212795, filed on November 22, 2024, which is incorporated herein by reference in its entirety.

### TECHNICAL FIELD

The present disclosure is related to the field of electronic devices, in particular an electronic device equipped with a wind deflector.

### BACKGROUND

With rapid technological advancement, the computational performance of electronic components has improved significantly while generating enormous heat. To prevent damage to electronic components from elevated temperature, fans must be incorporated into electronic devices to remove excess heat, enabling the electronic components to operate within a designated temperature range.

Typically, electronic products allow cooling airflow into the unit via intake fans and expel it through exhaust fans. When intake fans generate cooling airflow that enters the electronic device and absorbs heat, it readily escapes through gaps surrounding the intake fan and is subsequently re-drawn into the device, establishing a circulation loop. As a result, the heated air generated by the heat-absorbing cooling airflow cannot be expelled by the exhaust fan, so establishing a recirculation loop through the intake fan, which leads to decrease cooling efficiency.

### SUMMARY

Aspects of the disclosure provide an electronic device. The electronic device can include a housing including a housing body, a cover containing a first side panel and a second side panel, the housing having an accommodation space, the first and second side panels covering adjacent sides of the accommodation space, the first side panel having an air inlet, the second side panel having an air outlet, the air inlet and air outlet are configured to communicate with the accommodation space, an intake fan disposed in the accommodation space, the intake fan being adjacent to the first side panel, and a wind deflector disposed on the first side panel, the wind deflector having at least one ventilation opening corresponding to the intake fan, and the air inlet is configured to communicate with the accommodation space through the ventilation opening.

In an embodiment, the electronic device can further include a filter disposed within the accommodation space, wherein the filter and the wind deflector are assembled together and secured on the first side panel.

In an embodiment, the electronic device can further include at least one fastening element, the at least one fastening element passing through the filter and the wind deflector and securing the filter and the wind deflector to the first side panel.

In an embodiment, the first side panel can have at least one first assembly part, the filter has at least one second assembly part, the wind deflector has at least one third assembly part, the at least one second assembly part and the at least one third assembly part are disposed in the at least one first assembly part to enable the filter and the wind deflector to be installed on the first side panel.

In an embodiment, the first side panel can include a side panel body and an assembly body, the air inlet is disposed in the side panel body, the assembly body includes a protrusion structure, and the protrusion structure and the side panel body together constitute the first assembly part as a concave structure as its entirety..

In an embodiment, the electronic device can further include an exhaust fan adjacent to the second side panel.

In an embodiment, the wind deflector can be transparent. In another embodiment, the wind deflector can be made of polyvinyl chloride. In yet another embodiment, the wind deflector can have a thickness greater than or equal to 0.5 millimeters.

In an embodiment, the at least one ventilation opening can be circular or elliptical.

In an embodiment, the electronic device can further include a filter disposed between the first side panel and the wind deflector. In another embodiment, the electronic device can further include a filter disposed on a side of the wind deflector away from the first side panel.

### BRIEF DESCRIPTION OF DRAWINGS

Aspects of the present disclosure can be understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 illustrates a perspective view of an electronic device according to aspects of the present disclosure.

FIG. 2 illustrates an exploded view of the electronic device as shown in FIG. 1.

FIG. 3 illustrates a partially enlarged exploded view of the electronic device as shown in FIG. 1.

FIG. 4 illustrates another partially enlarged exploded view of the electronic device as shown in FIG. 1.

FIG. 5 illustrates a perspective view of the electronic device as shown in FIG. 1 with cooling airflow directions.

FIG. 6 illustrates an exploded view of the first side panel, second side panel, filter, and wind deflector according to aspects of the present disclosure.

### DETAILED DESCRIPTION

Detailed descriptions and technical contents of the present invention are illustrated below in conjunction with the accompanying drawings. However, it is to be understood that the descriptions and the accompanying drawings disclosed herein are merely illustrative and exemplary and not intended to limit the scope of the present invention.

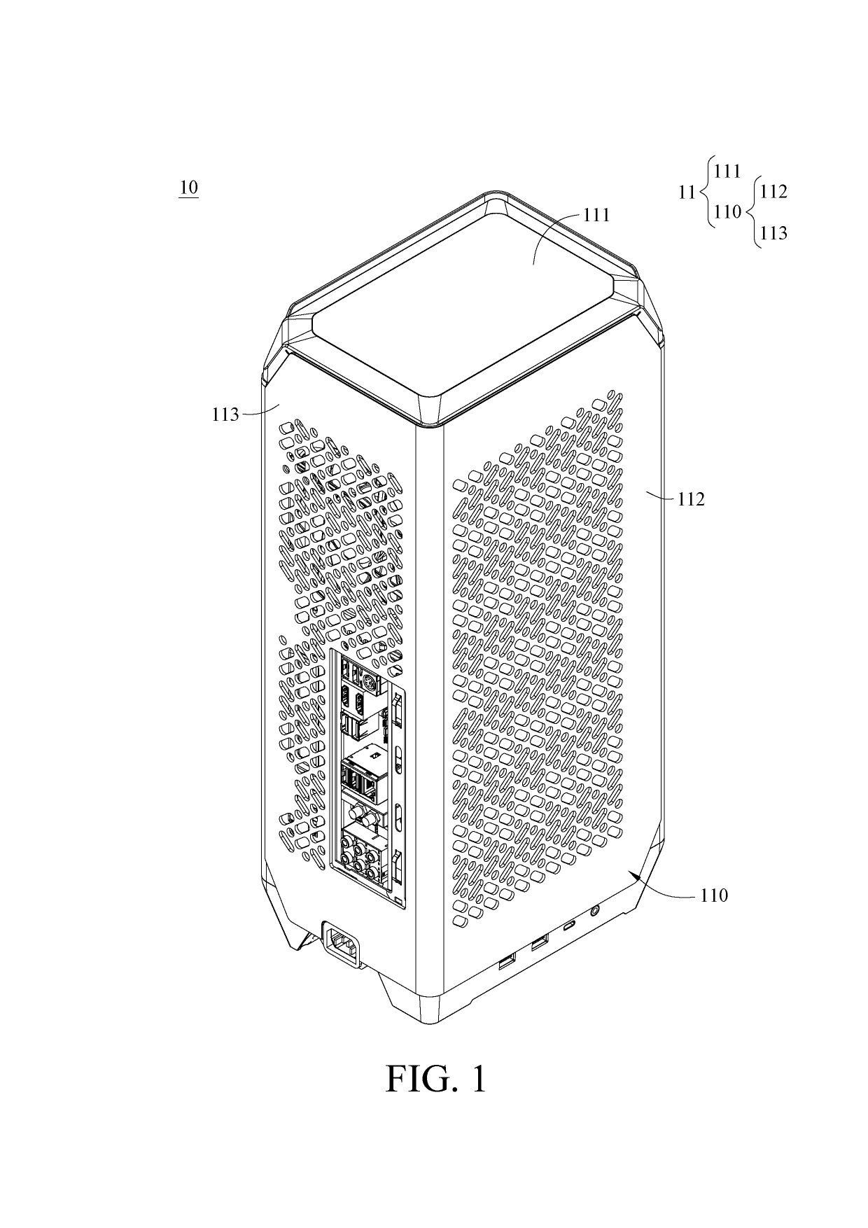

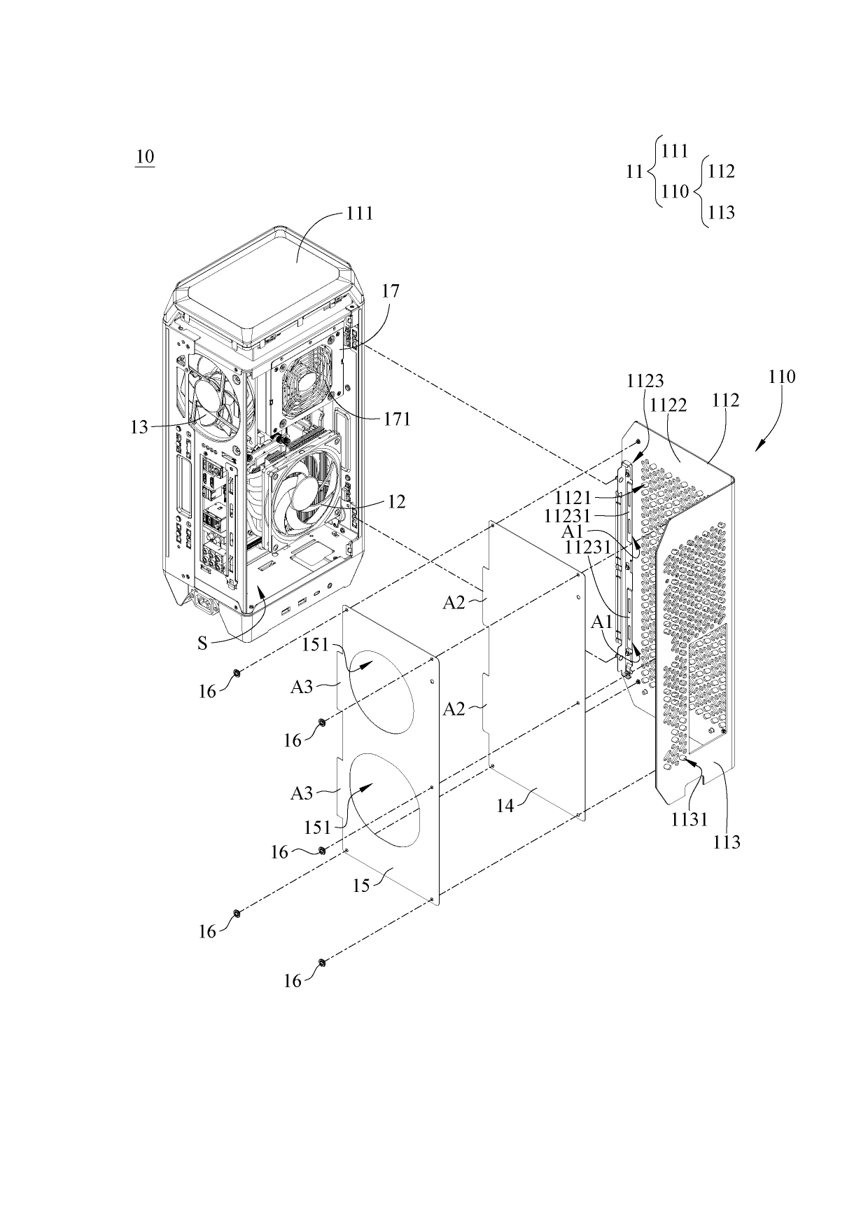

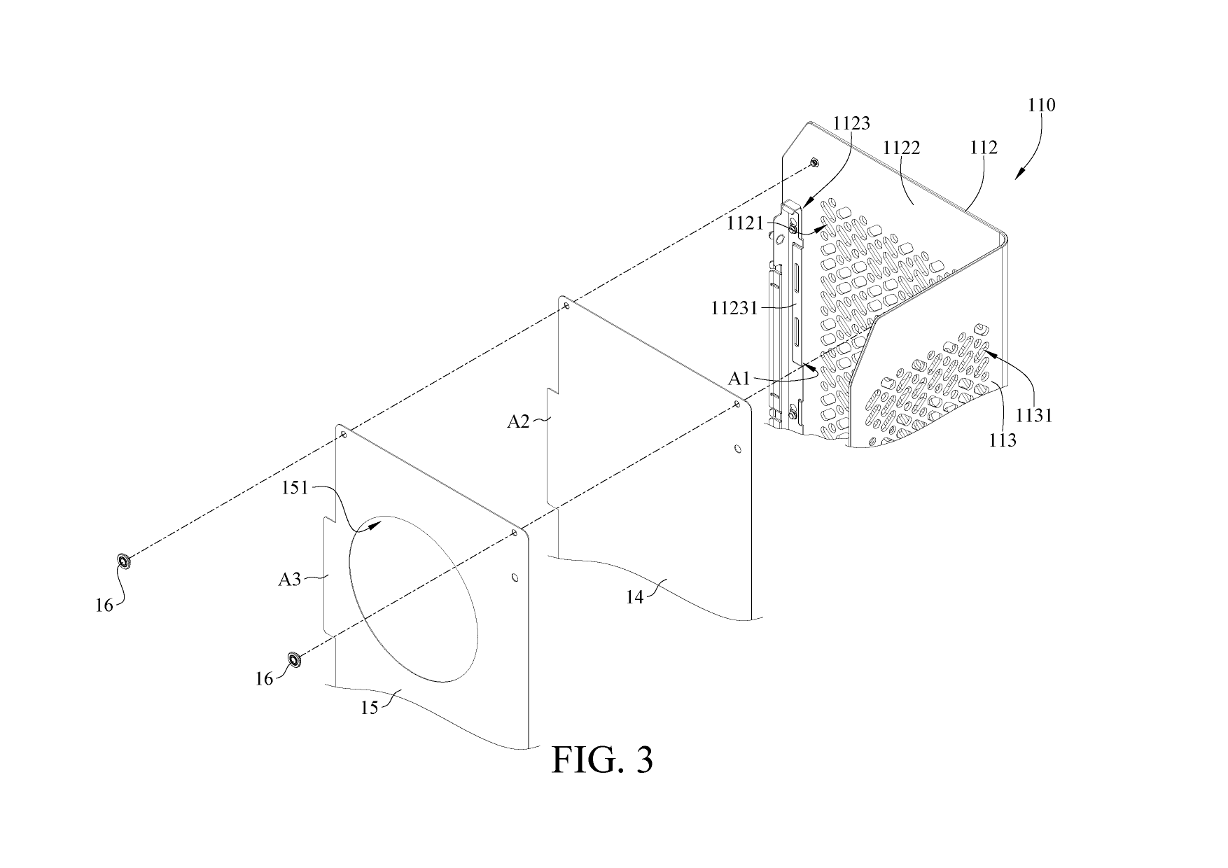

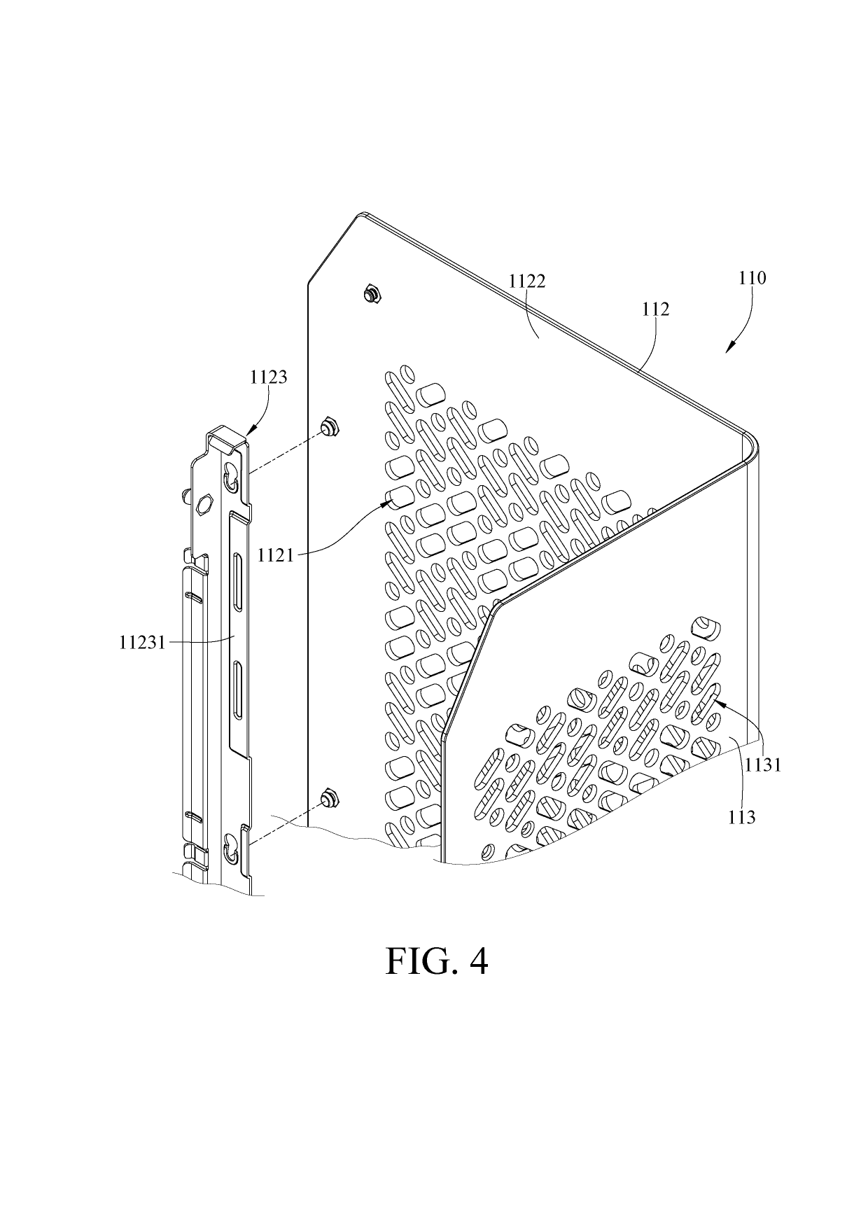

Please refer to FIGS. 1 to 4. FIG. 1 illustrates a perspective view of an electronic device according to aspects of the present disclosure. FIG. 2 illustrates an exploded view of the electronic device as shown in FIG. 1. FIG. 3 illustrates a partially enlarged exploded view of the electronic device as shown in FIG. 1. FIG. 4 illustrates another partially enlarged exploded view of the electronic device as shown in FIG. 1.

An electronic device 10 can include a housing 11, an intake fan 12, an exhaust fan 13, a filter 14, and a wind deflector 15. The electronic device 10 can be a computer system unit, server chassis, gaming console, or other computing device. The housing 11 can be made of metal materials such as aluminum, steel, plastic composites, or other suitable structural materials. The housing 11 includes six sides to form an accommodation space S. Further, the housing 11 includes a housing body 111, a cover 110 containing a first side panel 112, and a second side panel 113. The first side panel 112 and second side panel 113 are connected with one another and cover adjacent sides of the housing body 111.. The first side panel 112 has an air inlet 1121. The second side panel 113 has an air outlet 1131. The air inlet 1121, air outlet 1131, and accommodation space S are in communication. The air inlet 1121 and air outlet 1131 can be formed by a variety of patterns of openings, such as rounded rectangular through holes, circular through holes, hexagonal perforations, or other suitable ventilation configurations, which may be arranged in alternating, linear, or other efficient arrangement.

The intake fan 12 and exhaust fan 13 are disposed in the housing body 111 and located within the accommodation space S. The intake fan 12 is adjacent to the first side panel 112. The exhaust fan 13 is adjacent to the second side panel 113. The intake fan 12 generates cooling airflow flowing into the electronic device 10, while the exhaust fan 13 guides the cooling airflow out of the electronic device 10. The filter 14 is disposed on the first side panel 112 and located within the accommodation space S. The filter 14 is configured to filter the cooling airflow into the electronic device 10. Filter 14 can be made of, for example, plastic materials such as polyvinyl chloride.

The wind deflector 15 is disposed on the first side panel 112. The wind deflector 15 can be, for example, transparent. Additionally, the material of the wind deflector 15 is, for example, plastic materials such as polyvinyl chloride, and the thickness of the wind deflector 15 is, for example, greater than or equal to 0.5 millimeters. The filter 14 can be positioned between the first side panel 112 and the wind deflector 15. In some embodiments, the filter 14 can also be positioned between the first side panel 112 and the wind deflector 15. The wind deflector 15 includes two ventilation openings 151. The two ventilation openings 151 can be circular or approximately circular. One of the two ventilation openings 151 corresponds to the intake fan 12 disposed in the housing body 111, and the other corresponds to, for example, an power fan 171 disposed in a power supply unit 17. The air inlet 1121 communicates with the accommodation space S via the filter 14 and the two ventilation openings 151. The wind deflector 15 prevents, cooling airflow from escaping around the intake fan 12.

In one embodiment, the electronic device 10 may further include a plurality of fastening elements 16. These fastening elements 16 can be plastic snap fasteners that pass through the filter 14 and wind deflector 15 to be mounted to the first side panel 112. Therefore, the filter 14 and wind deflector 15 can be further secured to the first side panel 112 via these fastening elements 16.

In one embodiment, the first side panel 112 has two first assembly parts A1. Specifically, the first side panel 112 includes a side panel body 1122 and an assembly body 1123. The air inlet 1121 is arranged on the side panel body 1122. The assembly body 1123 has two protrusion structures 11231. Each of the protrusion structures 11231 and the side panel body 1122 together constitute the first assembly part A1 as a concave structure in its entirety. The filter 14 has two second assembly parts A2. The two second assembly parts A2 are, for example, convex structures. The wind deflector 15 has two third assembly parts A3. The two third assembly parts A3 are, for example, convex structures. The two second assembly parts A2 and the two third assembly parts A3 correspond with the two first assembly parts A1, respectively, in a concave-convex manner. The two third assembly parts A3 and the two second assembly parts A2 are respectively fitted into the two first assembly parts A1, allowing the filter 14 and wind deflector 15 to be assembled and fitted on the first side panel 112.

The air inlet 1121 is extensively distributed on the first side panel 112 for both aesthetic and ventilation needs. However, in existing electronic devices, the cooling airflow generated by intake fans is prone to unintended leakage and is repeatedly drawn in by the intake fans, causing the heated air formed by the heat-absorbing cooling airflow to recirculate through the intake fans, resulting in poor cooling efficiency. The electronic device 10 with the wind deflector 15 can prevent unintended leakage of cooling airflow, avoiding repeated intake of cooling airflow by the intake fan 12, thereby preventing heated air from forming recirculation through the intake fan 12 and resulting in low cooling efficiency. In this way, the temperature of various electronic components within the electronic device 10 can be reduced by, for example, 2°C, thereby improving cooling efficiency.

Furthermore, by adding the transparent wind deflector 15 to the first side panel 112 that already has a filter 14 in the existing structure, the electronic device 10 does not need to install additional foam on the intake fan 12 or rearrange the air inlet 1121, which would affect appearance consistency. This can enhance cooling efficiency of the fans 12, 13 for various electronic components while preserving the aesthetic design of the electronic device 10.

In one embodiment, the intake fan 12 can be installed on a CPU motherboard (not shown). The CPU motherboard can be moved within the housing body 111 to adjust the spacing between the intake fan 12 and the wind deflector 15. Specifically, the CPU motherboard can be disposed on an adjustable bracket (not shown). The adjustable bracket can be moved relative to the housing body 111 in a stepless or multi-step manner. In one embodiment, the CPU motherboard can be moved toward the first side panel 112 relative to the housing body 111 through the adjustable bracket, so that the intake fan 12 abuts against the wind deflector 15, ensuring there is no gap between the intake fan 12 and the wind deflector 15, preventing cooling airflow from escaping at the junction of the intake fan 12 and the wind deflector 15. In some embodiments, the CPU motherboard may not be moved relative to the wind deflector, and the gap between the intake fan and wind deflector can be filled with materials such as foam or rubber sheets.

In one embodiment, there is only one wind deflectors 15, and the ventilation opening 151 is circular to accommodate with most intake fans 12. In some embodiments, when the electronic device is required to install specific types of electronic components, the number of wind deflectors may increase, for example, to two. One of the two wind deflectors can have a circular ventilation opening that is compatible with most intake fans, while the other can have a ventilation opening that is elliptical, rectangular, or other shapes similar to circular or rectangular, tailed for specific types of intake fans. That is, after installing a universal wind deflector to cover most gaps around specific types of intake fans, a specifically designated wind deflector can be added to ensure that its the ventilation opening aligned with the specific type of intake fan. This allows wind deflectors to be more compatible with various types of electronic components.

In one embodiment, there are two ventilation openings 151, one for the intake fan 12 disposed in the housing body 111 and the other for the power fan 171 disposed in the power supply unit 17. In other embodiments, there may be only one ventilation opening, which corresponds to the intake fan 12 disposed in the housing body, or there may be multiple ventilation openings, each of which corresponds to the intake fan 12 disposed in the housing body and other fans disposed in other electronic components.

In one embodiment, the first assembly parts A1 are concave structures, and the second assembly parts A2 and third assembly parts A3 are convex structures. However, the present invention is not limited thereto. In other embodiments, the concave-convex connection between the first assembly parts A1, second assembly parts A2, and third assembly parts A3 may be reversed. That example, the first assembly parts A1 may also be convex structures, while both of the second assembly parts A2 and third assembly parts A3 may be concave structures.

In one embodiment, the first assembly parts A1, protrusion structures 11231, second assembly parts A2, and third assembly parts A3 each have two. However, the present invention is not limited thereto. In other embodiments, the number of first assembly parts A1, protrusion structures 11231, second assembly parts A2, and third assembly parts A3 could also be one, three, or more.

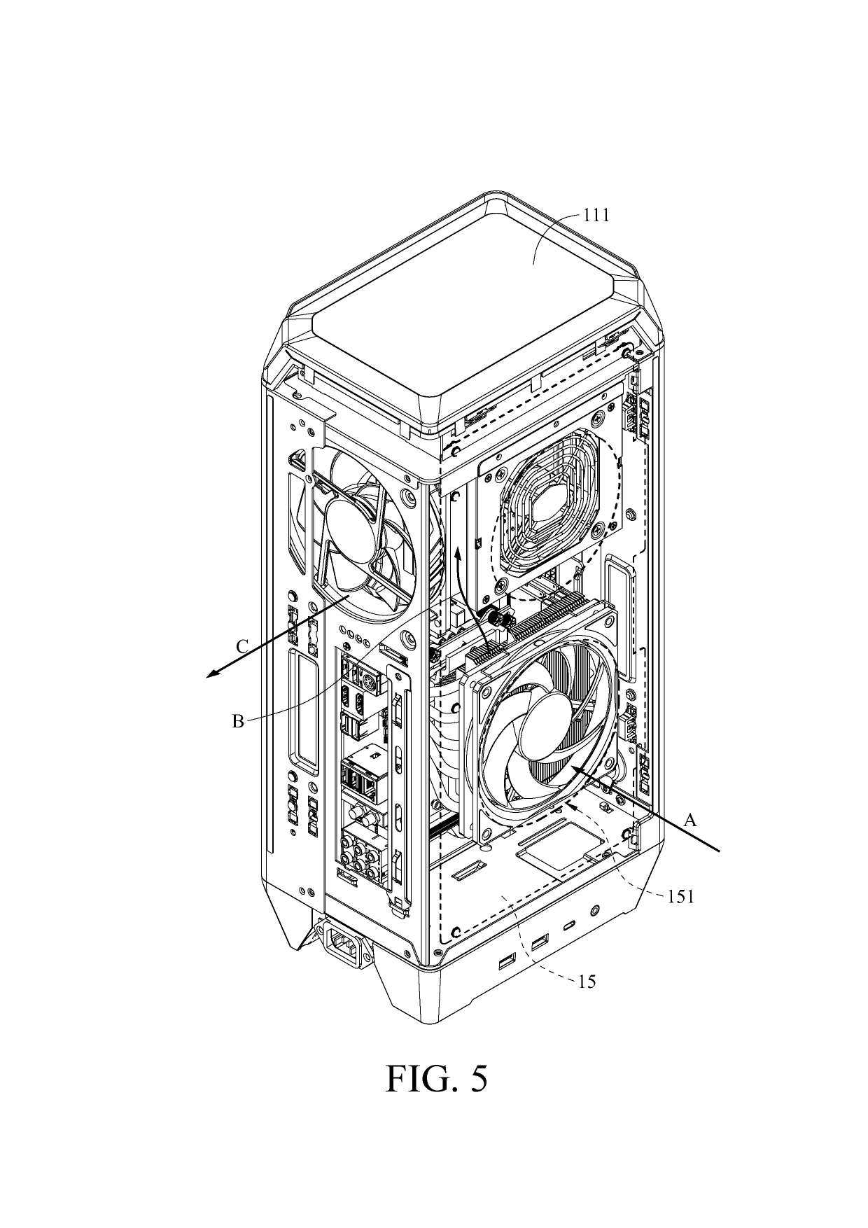

Refer to FIG. 5. FIG. 5 illustrates a perspective view of the electronic device as shown in FIG. 1 with cooling airflow directions. In one embodiment, when the intake fan 12 is in operation, the cooling airflow that flows into the electronic device 10 along direction A is generated. Next, the cooling airflow then passes through various electronic components along direction B within the electronic device 10 to dissipate heat generated during their operation. At this point, the wind deflector 15 blocks the cooling airflow within the electronic device 10 from escaping around the intake fan 12, preventing the intake fan 12 repeatedly absorbing cooling airflow and inhibiting it from flowing through the various electronic components. Subsequently, the cooling airflow flows is directed out of the electronic device 10 along direction C by the exhaust fan 13. This approach facilitate the cooling of numerous electronic components.

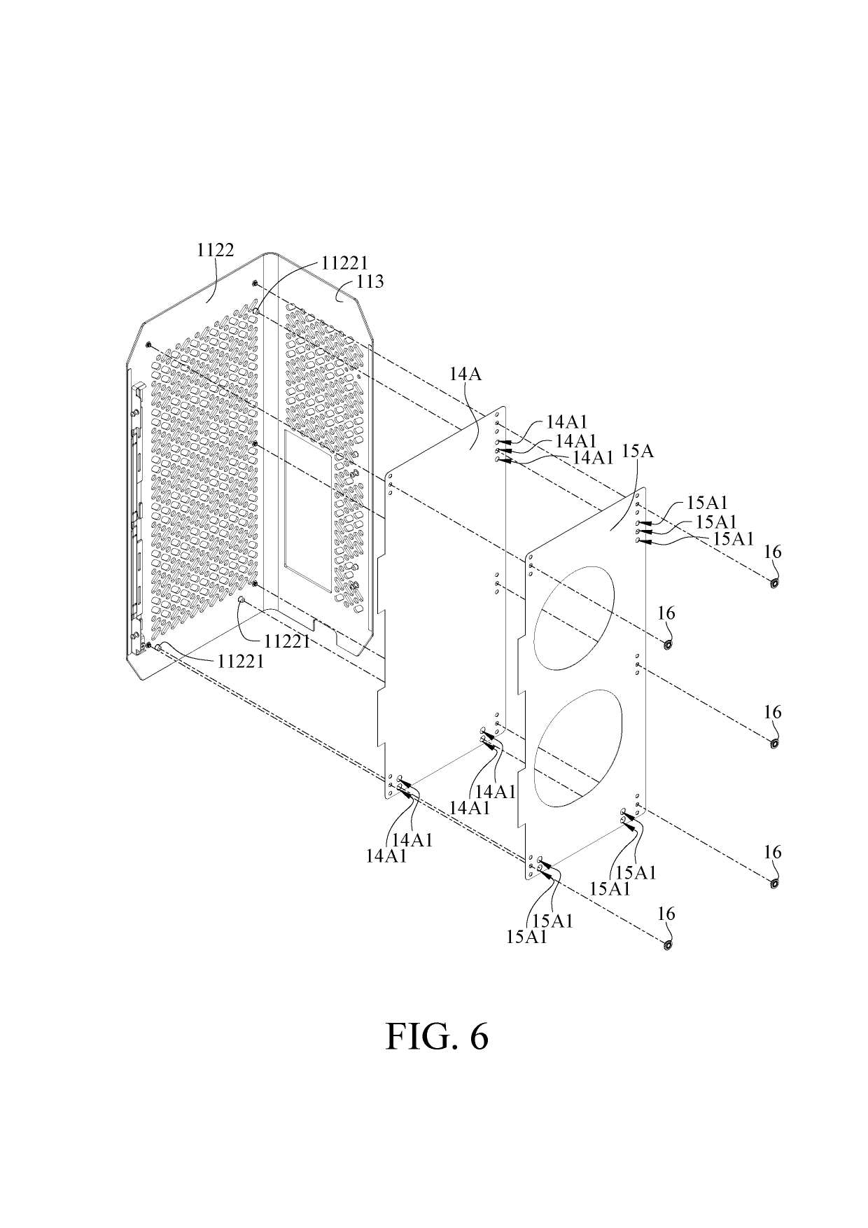

Please refer to FIG. 6. FIG. 6 illustrates an exploded view of the first side panel, second side panel, filter, and wind deflector according to aspects of the present disclosure. The first side panel 112, second side panel 113, filter 14A, and wind deflector 15A of this embodiment are similar to the first side panel 112, second side panel 113, filter 14, and wind deflector 15 of FIG. 1.

In this embodiment, the corners of the side panel body 1122 of the first side panel 112 have a plurality of positioning posts 11221, the corners of the filter 14A have a plurality of first positioning holes 14A1, and the corners of the wind deflector 15A have a plurality of second positioning holes 15A1. These first positioning holes 14A1 correspond to these second positioning holes 15A1, and these first positioning holes 14A1 and second positioning holes 15A1 can be selectively positioned on these positioning posts 11221. The positions of the filter 14A and wind deflector 15A on the side panel body 1122 can be adjusted based on the specifications of the intake fan 12 (as shown in FIGS. 1 to 5) or the configuration of the intake fan within the accommodation space S (as shown in FIGS. 1 to 5).

Because the electronic device includes the wind deflector 15 to prevent unintended leakage of cooling airflow, so stopping the intake fan from repeatedly drawing in cooling airflow and avoiding the recirculation of heated air, which would compromise cooling efficiency. In this approach, the temperature of various electronic components can be decreased by up to 2°C, enhancing cooling efficiency.

Furthermore, the electronic device no longer necessitates the installation of additional foam on the intake fan or the modification of the air inlet arrangement, as the first side panel that already includes the filter 14 with the wind deflector 15, thereby maintaining aesthetic uniformity. As a result, the present disclosure enhances cooling efficiency of fans for various electronic components while preserving the aesthetic design of the electronic device.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. An electronic device, comprising:
a housing including a housing body, a cover containing a first side panel and a second side panel, the housing having an accommodation space, the first and second side panels covering adjacent sides of the accommodation space, the first side panel having an air inlet, the second side panel having an air outlet, the air inlet and air outlet are configured to communicate with the accommodation space;
an intake fan disposed in the accommodation space, the intake fan being adjacent to the first side panel; and
a wind deflector disposed on the first side panel, the wind deflector having at least one ventilation opening corresponding to the intake fan, and the air inlet is configured to communicate with the accommodation space through the ventilation opening.

2. The electronic device of claim 1, further comprising a filter disposed within the accommodation space, wherein the filter and the wind deflector are assembled together and secured to the first side panel.

3. The electronic device of claim 2, further comprising at least one fastening element, the at least one fastening element passing through the filter and the wind deflector and securing the filter and the wind deflector to the first side panel.

4. The electronic device of claim 2, wherein the first side panel has at least one first assembly part, the filter has at least one second assembly part, the wind deflector has at least one third assembly part, the second assembly part and the third assembly part are fitted into the first assembly part to enable the filter and the wind deflector to be secured to the first side panel.

5. The electronic device of claim 4, wherein the first side panel includes a side panel body and an assembly body, the air inlet is disposed on the side panel body, the assembly body includes a protrusion structure, and the protrusion structure and the side panel body together constitute the first assembly part as a concave structure as its entirety.

6. The electronic device of claim 1, further comprising an exhaust fan adjacent to the second side panel.

7. The electronic device of claim 1, wherein the wind deflector is transparent.

8. The electronic device of claim 1, wherein the wind deflector is made of polyvinyl chloride.

9. The electronic device of claim 1, wherein the wind deflector has a thickness greater than or equal to 0.5 millimeters.

10. The electronic device of claim 1, wherein the ventilation opening is circular or elliptical.

11. The electronic device of claim 1, further comprising a filter disposed between the first side panel and the wind deflector.

12. The electronic device of claim 1, further comprising a filter disposed on a side of the wind deflector away from the first side panel.
